(19) United States
(12) Patent Application Publication
(10) Pub. No.: US 2015/0001179 A1
(43) Pub. Date: Jan. 1, 2015

(54) METHOD FOR PRODUCING ETCHABLE STRUCTURES USING A LASER HAVING A WAVELENGTH IN THE INFRARED RANGE

(71) Applicant: Sandvik Surface Solutions Division of Sandvik Materials Technology Deutschland GmbH, Ennepetal (DE)

(72) Inventors: Ralf Niggemann, Klerspe (DE); Heiko Peuster, Wuppertal-Beyenburg (DE)

(21) Appl. No.: 14/376,245

(22) PCT Filed: Feb. 1, 2013
(86) PCT No.: PCT/EP2013/052087

§ 371 Date: Aug. 1, 2014

(30) Foreign Application Priority Data
Feb. 3, 2012 (DE) 10 2012 100 915.5

(51) Int. Cl. G03F 7/00; B29C 33/38

(52) U.S. Cl. CPC G03F 7/0017; B29C 33/3857
USPC 216/48; 264/400

(57) ABSTRACT

The invention relates to a method for producing etch-resistant structures (masks) on the surfaces of metallic pressing tools, specifically continuous press bands or press plates, by means of a laser, wherein a surface of the press tool to be structured is provided with a thermally sensitive, etch-resistant coating and the laser burns structures out of the etch-resistant coating. In order to prevent negative influences when lasering on the surface of the press plate, the invention proposes that the structure is burned with a laser that emits light having a wavelength in the infrared range between 780 nm and 1 mm.

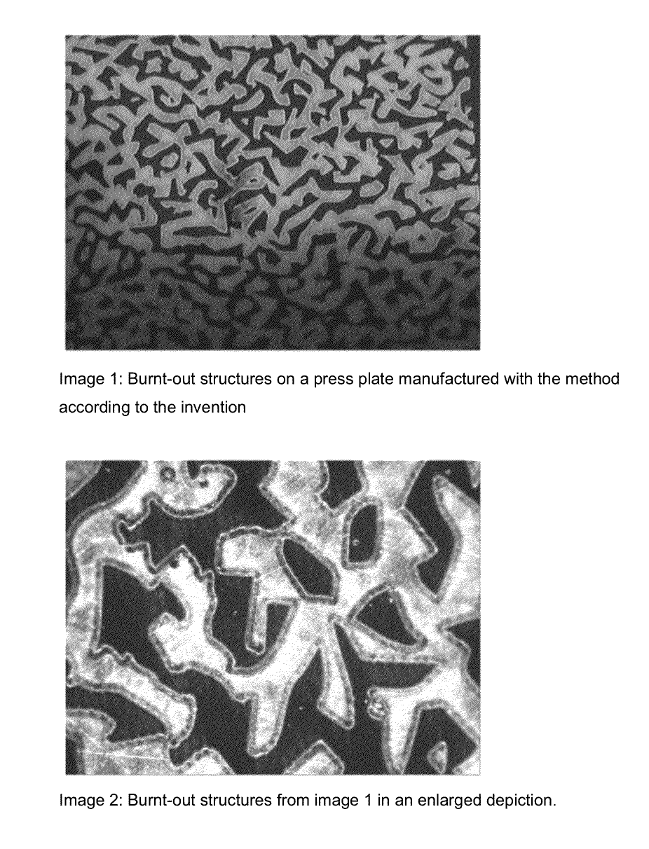

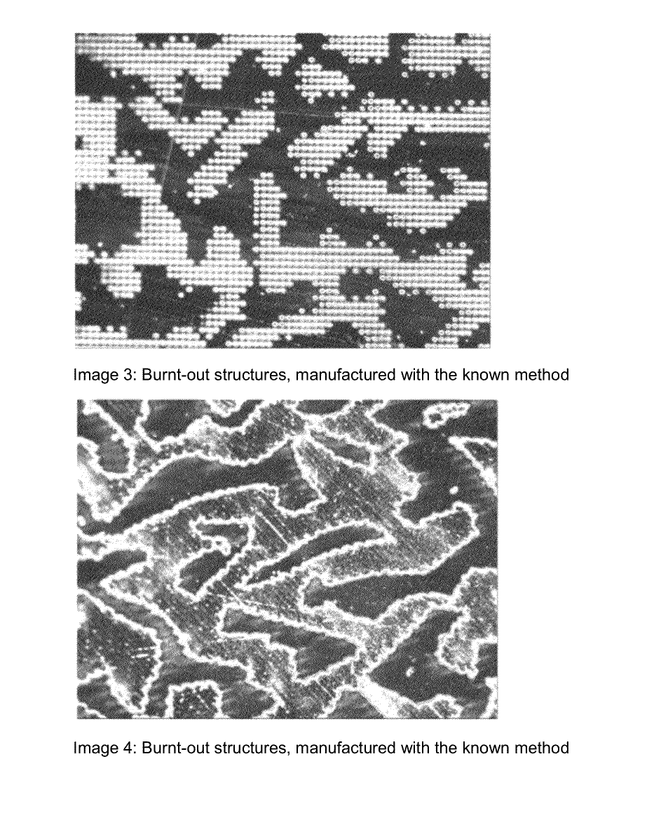

The invention relates to a method for producing etch-resistant structures (masks) on the surfaces of metallic pressing tools, specifically continuous press belts or press plates, by means of a laser, wherein a surface of the pressing tool to be structured is provided with a thermo-sensitive, etch-resistant coating and the laser burns structures out of the etch-resistant coating.

Surface-structured, large continuous press belts and press plates serve to provide plate or belt material with a surface structure for decorative or technical purposes. Surface-structured plate or belt material is, for example, used in the furniture, floor, construction and commercial vehicle industry (e.g. floors for loading areas).

The plate material is, for example, manufactured from diverse plastics. Likewise, chipboard, plywood and MDF boards are used, which are coated with films/papers/decorations that are soaked in melamine resin on the use side (upper side) or the lower side. In the production of floors or commercial vehicle floors as well as in construction panels, a defined proportion of corundum materials is additionally added to the melamine film/paper on the use surface in order to give the plate use surface the required wear resistance. For decorative applications, the surfaces of the plates are provided with decorative structures, such as, for example, wood, stone or other structures (pearl-shaped, finely striped surface structures, etc.). Plates for the construction and commercial vehicle industry, for example, receive technical geometric structures, such as rhombuses, saucers or fluting (in order, for example, to bring about slip-resistance).

Double belt and hot presses are used in the manufacturing of the plate material. Individual plates or panelled plate stacks are used in the hot presses. In the presses, items to be embossed (plates to be embossed) are pressed using defined pressure and temperature.

The manufacture of the named pressing tools occurs by application of a structured, etch-resistant mask onto the surface of the press plate or continuous press belt to be structured. The etch-resistant mask is usually imprinted onto the surface. After the etching, the mask is removed mechanically or electrolytically and the surface is cleaned. This procedure is repeated with different structures until the desired end structure is achieved. As a rule, the structured surface of the tool is then chromed. Thus its life span is increased, a defined gloss level of the plate surface to be manufactured is set and an easier demolding of the plate (removal of the press plate from the plate) is enabled after the pressing. The structure of the surface of the pressing tool then corresponds to the negative of the surface structure to be produced on the plate material.

The imprinting of the etch-resistant mask usually occurs with a print roller. A disadvantage of conventional printing methods exists in that the printing procedure is imprecise. The colour applied with the print roller runs slightly, such that deviation in the mask compared to the graphically (often digitally) created mask template cannot be avoided 100%. This unfavourable influence is increased even more on a structure that has already been etched, as the structure/contour edges cause a slight running of the print colour. Another disadvantage exists in that the print roller cannot transfer the mask 100% in the case of already etched surfaces (particularly in the case of deep etching) due to deep, partially very narrow structural elements. Consequently, print colour is partially missing in the structural valleys. The mask is therefore only incompletely displayed there and can, correspondingly, in the subsequent etching procedure, only be etched into the surface incompletely. Further disadvantages exist in that it cannot be printed without pattern, that the print image is not defined and can be placed synchronously to later produced decorations and that drying times of the medium must be considered.

A mask can also be produced by application of a photoresist. This occurs in that the photoresist applied to the pressing tool is covered with a film, which has the desired structure, and is exposed. Therein the exposed (or the not exposed) parts of the photoresist (positive/negative photoresist) are set. After the exposure, the non-set parts are chemically removed from the tool surface. A structured mask remains on the tool. The tool surface is then etched. Subsequently, a cleaning and, if necessary, a further application of another mask occurs with subsequent further etching. This procedure is repeated with different masks until the desired end structure is achieved in the surface of the pressing tool.

The photo technical method also has significant disadvantage. In the case of large pressing tool surfaces, a problem exists in that a film must be composed of several film pieces and stuck together, as no sufficiently large film is available. Undesired irritations result on the sticking edges during the development of the photoresist, which must be elaborately manually corrected before etching. In addition the photographic chemicals affect employees and pollute the environment. Furthermore, the procurement and disposal of the photoresist is elaborate and expensive. Finally, the method is more work-intensive than a conventional printing method, as additional processes are required (exposure, washing-off of the non-set photoresist). Usually, the photo technical method is not applicable technically and economically for continuous press belts.

A method is known from DE 40 33 230 C2 of the type named at the beginning to emboss embossing gravures onto large press plates or continuous belts for the surface treatment of webs or plates made from plastic, in which the press plate or continuous belt is firstly covered over the entire area with a carrier web made of plastic, a galvanic metal layer or an etch-resistant colour film. Then an embossing structure covering only the thickness of the coating is produced with laser beams. Subsequently, the bare metal points of the press plates and/or the continuous belts undergo an etching treatment.

Until now, laser methods have not yet been used for manufacturing etchable masks for the industrial production of continuous press belts or press plates. This could be because the digital depiction of a mask in large size represents a problem. In the case of large press plates of, for example, more than 8 m², the structural image applied to the press plate is distributed into different fields, so-called tiles, the structural images of which are applied to the press plate consecutively. The data volumes of the structural image to be processed for the control of the laser head hereby remain manageable. Thus a uniform structural image results; the individual tiles overlap. A disadvantage of this procedure is, however, that undesired, visible edges result in the structure of the mask burnt out with the laser in the tile regions that overlap. Furthermore, due to the laser technology, the burnt-out edges of the structure are scruffy; the required edge definition is lacking. Furthermore, visible irritations in the structure remain on the tool surface after etching, which make the structural image no longer saleable.

Thus a problem on which the invention is based consists in making available a suitable method of the type named at the beginning in which the named problem does not occur or occurs in an at least significantly reduced manner.

This object is solved with a method having the features of claim 1.

It was surprisingly determined that the occurrence of edge effects on the processed pressing tool can be avoided if the coating is burnt out with a laser, which emits with a wavelength in the infrared range between 780 nm and 1 mm. This could be because a laser beam having a wavelength in the infrared range is only very slightly engaged with the metallic surface and is reflected to a very high degree (75% or more). Compared to other lasers, in particular working in the UV range, less heat is thus dissipated into the surface of the pressing tool. Thus the laser can indeed effectively burn out a structure from the etch-resistant coating, wherein at the same time it leaves the properties of the metal surface of the pressing tool uninfluenced.

CO₂ lasers have been emphasised as particularly suitable, which produce a laser beam with a wavelength of 10.6 μm.

Laser beams of a YAG laser having wavelengths of 1064 nm, 946 nm, 1320 nm or 1444 nm have also proved suitable for the method according to the invention.

The method according to the invention is particularly suitable for producing etch-resistant structures on large press plates having a width and a length of more than 1 m respectively, wherein the press plate is mounted on a table, in particular a vacuum table, and the laser is moveable above the press plate relative to the press plate. Therein, optionally, the table and/or the laser head are able to be moved at least in two directions. The method according to the invention is also particularly suitable for very large press plates with a structured surface of a size of 6 m² or more, or even 8 m² and above.

Naturally, the method according to the invention can also be used for a continuous press belt, wherein then the continuous press belt is conveyed past a laser that is moveable in one direction.

In the case of both applications, the laser head or the laser is typically adjustable and controllable in height compared to the pressing tool. If the laser beam is focussed, preferable by means of a lens, then the focus of the laser beam is positioned exactly for an optimal burning-out of the coating.

Especially in the case of large press plates, it is useful, and in the case of current control technology even necessary, that the laser processes the coating in different sections, which are, in particular, tile-shaped. In this case, it is particularly preferred if a head bearing the laser is positioned over a section and the laser burns the structure out of the coating line by line, and wherein the contour of the structure introduced into the coating is driven around by the laser beam at the end of the processing.

To burn out the coating, the laser is preferably operated in pulsed operation, wherein the individual pulses are set such that burnt-out points lying next to one another, as well as points of neighbouring lines, overlap. In the case of a sufficiently powerful laser, the burning-out can also occur in continuous wave operation.

At the end of the method according to the invention it is useful to clean the pressing tool, after burning out the coating, with a solvent, in particular with an alcohol, preferably with ethanol, wherein the ethanol can be denatured with 1% 2-butanone.

In a possible variant for preparing the laser burning out method, the pressing tool provided with an etch-resistant coating is orientated towards the laser.

This occurs for a press plate, for example, as follows: the press plate is laid on a vacuum table and orientated roughly towards guides for a support arranged in the longitudinal direction of the table. The support bears a laser, wherein the laser is mounted moveably, transversely to the support guides, on the support and is driven with a motor. After the occurrence of the rough orientation, the vacuum is activated such that the press plate is fixed and lies on the vacuum table evenly.

The table can be moved 2-dimensionally on the horizontal, independently of the support guides. For the fine orientation of the press plate compared to the support guides, two opposing reference points are marked on the press plate, which can be driven into by the laser. For this purpose, firstly, a first reference point is driven into on the press plate and the position stored in the control of the laser head as such. Then the laser is moved over the long table side to the opposing reference point. The table is moved such that the laser meets the second reference point during its movement in the direction of the support guides. This position is also stored in the control of the laser head. Then the laser is moved back again to the first reference point. Should the position of the first reference point have moved due to the movement of the table, the entire procedure can be repeated until the reference point can be driven into exactly with the laser control. Alternatively to this, the first reference point can be driven into again by the control of the laser head, without the table being orientated again, wherein due to the thus determinable offset between the original position of the first reference point and the then current position of the reference point from the control of the laser head or a computer for the specification of the structural image, the position of the structural image or its tiles on the press plate can be calculated.

For the preparation of a continuous press belt provided with an etch-resistant coating, the belt is positioned in studding between two opposing cylinders. The studding is constructively designed such that a 100% directional stability of the belt is possible. The laser beam source is applied opposite one of the cylinders. The positioning of the laser occurs such that the laser beam runs radially to the cylinder. Thus a contour-defined burning-out of the structure is possible.

The route control for the laser for the burning-out of the coating on a press plate according to the invention can occur, for example, tile by tile. For this purpose, the laser is moved into a position over an intended quadratic or square tile section on the press plate, preferably into a position plumb above the midpoint of the tile. From this point, the laser burns the desired structure out of the coating line by line. For this purpose, the laser is mounted to be able to swivel in the support. After the laser has left all lines of the tile and has removed the coating in the desired positions, it is preferably driven again along the contours of the structures to be burnt out in order to give a smooth contour to the burnt-out structure. Then the laser is moved into a position over a further tile. From there, it then burns the structure into the coating of this intended tile.

The tile-by-tile processing of the coating is, in particular, owed to the possibility of the control of a laser. It is also conceivable to allow the laser to move line by line over the entire width (or length) of the press plate, if the support of the laser allows a corresponding error-free guidance. This procedure has the advantage that a mounting of the laser so that it is able to swivel can be dispensed with and the laser beam always strikes plumb on the coated press plate. A mounting of the laser so that it is able to swivel can then also be dispensed with if the laser can be moved inside the supports in two directions parallel to the surface of the press plate, such that the laser beam is moveable line by line within a tile and it always strikes plumb on the press plate. Thus the structure to be burnt out is able to be contoured in a particularly defined manner.

The route control of the laser during burning-out of the coating on a continuous press belt occurs, on the one hand, transversely to the belt, wherein the belt is further transported after each driving-over of the laser around a line feed. In this case, the belt is driven intermittently from the cylinders. The belt can, however, also be moved longitudinally to the laser, wherein after each revolution of the laser, a line feed of the laser occurs in the transverse direction. As a further possibility, the burning out can also occur in a spiral shape. Therein the laser is controlled in a spiral-shaped burning out of the coating such that a burnt-out mask results without any holes.

As results from the above, the method according to the invention is conceived as part of a method for producing a structured surface of a press plate or press belt. Therein the press plate, after it has been provided with an etch-resistant structure according to the invention, is etched, in order to produce a surface structure on the press plate or press belt. Subsequently, the etch-resistant structure is removed from the surface. These method steps can be repeated according to need for producing a more complex surface structure of the press plate, wherein, in particular, the etching depths of the individual etching steps are varied.

The following images 1 and 2 show the result of the laser burning-out with the method according to the invention, in which the contours of the coating were driven over with the laser. Images 3 and 4 show the result of a laser burning out method, in which the contours of the contours to be burnt out were not driven over. Compared to images 3 and 4, it can be clearly recognised in images 1 and 2 that the burnt-out structures have smooth edges and thus a clear contour. Compared to this, the contours in the structure, which were manufactured with a conventional laser burning out method and are shown in images 3 and 4, are lacerated.

1. A method for producing etch-resistant structures on a surface of a metallic pressing tool, the method comprising:
providing a surface of the pressing tool to be structured with a thermo-sensitive, etch-resistant coating; and
using a laser that emits light having a wavelength in the infrared range between 780 nm and 1 mm to burn structures out of the etch-resistant coating.

2. Method The method according to claim 1, wherein the laser is a CO₂ laser having a wave length of 10.6 μm.

3. The method according to claim 1, wherein the laser is a YAG laser and emits with a wavelength of 1064 nm, 946 nm, 1320 nm or 1444 nm.

4. The method according to claim 1, wherein the pressing tool is a large press plate having a width and a length of more than 1 m, respectively, wherein the press plate is mounted on a vacuum table, and wherein the laser is moveable above the press plate relative to the press plate.

5. The method according to claim 1, wherein the laser processes the coating in different sections, which are tile-shaped, wherein a head bearing the laser is positioned over a section and the laser burns the structure out of the coating line by line, and wherein the contour of the structure introduced into the coating is driven around with the laser beam at the end of the processing.

6. The method according to claim 1, wherein the laser is operated to burn out in pulsed operation, wherein individual pulses are set such that burnt-out points lying next to one another, as well as points of neighbouring lines, overlap.

7. The method according to claim 1, further comprising cleaning the pressing tool is cleaned, after the burning-out of the coating, with a solvent.

8. A method for producing a structured surface of a press plate or press belt, the method including:
producing an etch-resistant structure with a method according to claim 1,
etching the surface provided with the etch-resistant structure, and
removing the etch-resistant structure from the surface.

9. The method according to claim 1, wherein the metallic pressing tool comprises a continuous press belt or press plate.

10. The method according to claim 7, wherein the solvent is an alcohol.

11. The method according to claim 10, wherein the solvent is one of ethanol or ethanol denatured with 1% 2-butanone.

12. The method according to claim 8, further including repeating said producing, said etching, and said removing according to need to produce a complex surface structure of the press plate.
